(19) United States
(12) Patent Application Publication
(10) Pub. No.: US 2015/0325503 A1
(43) Pub. Date: Nov. 12, 2015

(54) Method of singularizing packages and leadframe

(71) Applicant: Infineon Technologies AG, Neubiberg (DE)

(72) Inventors: Lim LAY YEAP, Batu Berendam (MY); Khoo Nee Wan, Melaka (MY); See Thiong Zhou, Batu Berendam (MY)

(73) Assignee: Infineon Technologies AG, Neubiberg (DE)

(21) Appl. No.: 14/272,568

(22) Filed: May 8, 2014

(51) Int. Cl. H01L 23/495; H01L 23/31; H01L 21/78

(52) U.S. Cl. CPC H01L 23/49541; H01L 23/49575; H01L 21/78; H01L 23/3114

(57) ABSTRACT

A method of singularizing a matrix array of packages is provided, wherein the method comprises providing a matrix array of packages, wherein the matrix array is formed on a leadframe; cutting predefined leads of the leadframe by a punching process; and singularizing the packages of the matrix array of packages by a sawing process.

### TECHNICAL FIELD

Various embodiments relate to methods of singularizing packages and to a leadframe.

### BACKGROUND

Semiconductor chips are fabricated, tested and packaged for manufacturing electronic modules. With the conventional semiconductor plastic packaging processes, several chips are processed simultaneously on a carrier called leadframe and a so called matrix array of packages is formed. After the packaging has been completed and leads have been cut and finally formed (e. g., bent in a same direction to permit board mounting), singulating a device or chip package from the leadframe is performed as follows. The device is still held by tie bars (which are pieces of the leadframe) to a leadframe outer rail. During the conventional singulation operation, the device is pushed up by a punch while the rails are being held in position, the tie bars eventually break off. Ties bars are broken off by yielding the material of the tie bars in a combination of bending and normal stress during the punching process.

The cut or broken tie bars typically protrudes after the punching process leading to potential damages of mold compounds of other packages by knocking or colliding of the protruding tie bars.

### SUMMARY

Various embodiments provide a method of singularizing a matrix array of packages, wherein the method comprises providing a matrix array of packages, wherein the matrix array is formed on a leadframe; cutting leads of the leadframe by a punching process; and singularizing the packages of the matrix array of packages by a sawing process.

Furthermore, various embodiments provide a matrix array of packages, the matrix array of packages comprising a leadframe comprising a plurality of chip reception areas arranged in a matrix array comprising rows and columns; and an encapsulation material encapsulating at least a part of the leadframe, wherein the encapsulation material comprising a predefined cutting area extending perpendicular to rows of the matrix array, wherein the predefined cutting area has a width of less than 0.50 mm.

Moreover, various embodiments provide a method for manufacturing a plurality of chip packages, wherein the method comprises providing a leadframe comprising a plurality of chip reception areas; assembling at least one electronic chip onto each of the plurality of chip reception areas; forming a plurality of packages by molding an encapsulation material onto the assembled electronic chips; cutting leads of the leadframe by a punching process; and singularizing the plurality of packages by a sawing process.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIGS. 1A and 1B schematically show a leadframe according to an exemplary embodiment;

FIGS. 2A to 2C schematically show a compression molding process;

FIGS. 3A and 3B schematically show a matrix array of packages comprising a leadframe of FIG. 1 after the compression molding process;

FIG. 4A and 4B schematically show the matrix array of FIG. 2 and illustrating a punching step;

FIG. 5 schematically shows a cross sectional view of the matrix array of FIG. 4 illustrating a sawing process;

FIG. 6 schematically illustrates a flow chart of a singularizing method according to an exemplary embodiment; and

FIG. 7 schematically illustrates a method of manufacturing a plurality of chip packages.

### DETAILED DESCRIPTION

In the following further exemplary embodiments of a test probe and a method of manufacturing a test probe will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a leadframe for a matrix array of packages wherein the leadframe is adapted to be cut by a sawing process. In particular, the leadframe may be adapted to be used for a matrix array of packages wherein the singularizing is performed in a hybrid manner, i.e. by two different separation steps or sub-steps. For example, a first step, which is performed by punching, disconnects or separates predefined leads of the leadframe, while a second step is performed by sawing, e.g. along a predefined cutting area, e.g. formed by two cutting lines, of the leadframe and/or an encapsulation material at least partially encapsulating the leadframe, which second step singularize or separate the packages from each other.

In particular, the packages may be dual-flat no-lead (DFN) packages, for example. Each package may comprise at least one electronic chip, e.g. a transistor or power transistor. The leadframe may be a copper leadframe and/or may be produced by a stamping process. The encapsulating material may be mold compound or laminate or polymer based material.

In particular, the predefined cutting area may form a predefined breaking point or breaking line. That is, a “predefined cutting area” may be a portion or section of the leadframe which is intended to be cut or broken later in the process for separating the formed packages. In addition or alternatively the predefined cutting area may be formed on the leadframe or in an encapsulation material arranged on or at least partially enclosing the leadframe and optional electronic chips arranged on the leadframe. It should be noted that the predefined cutting area may define or form the separation between two columns of the matrix array. That is, the predefined cutting area runs perpendicular to the rows or strips of the matrix array. In particular, the width of the predefined cutting area, e.g. formed by a distance between two cutting lines, is defined in the direction which is parallel to the row or strip of the matrix array. In particular, the leadframe may comprise or may consist of copper or aluminum or any other suitable conductive material.

It should be noted that it may be possible to use such a narrow predefined cutting area or line, since the separating or singularizing of the packages of the matrix array of a single row may be performed afterwards by a sawing process and not by a punching process. When using a punching process for separating the packages (as used in commonly known processes) a distance between the packages of more than 1 mm (e.g. between 1.5 mm and 3.1 mm) would have to be maintained in order to ensure that the punching process does not damage the packages.

Thus, in that sense a leadframe for a matrix array of packages is provided which leadframe or the total matrix array of packages is adapted to be cut by a sawing process. In particular with respect to the separating, the leadframe is adapted to be processed afterwards in a method according to an exemplary embodiment.

It should be noted that of course the naming or determining of rows and columns of the matrix array can be interchanged in principle.

According to a method of separating a matrix array of packages according to an exemplary embodiment a hybrid cutting or separation process may be provided. The hybrid process may produce a package outline which is similar to known processes but enabling a higher density of packages in the matrix array and/or more robust package without changing the package footprint or size.

In the following further exemplary embodiments of the method of singularizing a matrix array of packages are described. However, the features and elements of the described embodiments may also be combined with the leadframe or matrix array of packages and the method of manufacturing a plurality of chip packages according to an exemplary embodiment.

According to an exemplary embodiment of the method the punching process is performed before the sawing process is performed.

By performing the punching process or punching step before the sawing step it may be possible to test a plurality of packages, e.g. a complete row or column, of the matrix array while they are still mechanical connected to each other. In particular, the punching process separates the packages from each other by cutting the leads of the leadframe, while the packages are still mechanical connected to each other.

According to an exemplary embodiment the method further comprises testing at least one package of the matrix array before the sawing process is performed.

Preferably the testing is performed after the punching step used for cutting or separating leads or predefined leads of the leadframe relating to different packages. In particular, the testing may be a strip testing, i.e. several or all packages of a strip or row of packages may be tested simultaneously. Thus, it may be possible to simplify the testing of a great number of packages.

According to an exemplary embodiment of the method the testing is performed for a plurality of packages of a row of the matrix array of packages simultaneously.

In particular, all packages of a row may be tested simultaneously. The testing of several or all packages of one strip or row may be in particular advantageous for packages used in products that does not require electrical isolation of an included heatsink.

According to an exemplary embodiment the method further comprises marking the at least one tested package.

In particular, all tested packages or all packages of a strip or row may be marked. The marking may indicate some information concerning the results of the testing, e.g. whether some quality requirements or quality standards are met or not. The marking or labelling may be performed by any suitable process, e.g. by laser marking.

According to an exemplary embodiment the method further comprises forming the matrix array of packages by assembling a plurality of electronic chips onto the leadframe; and forming an encapsulation material on the leadframe by compression molding.

In particular, the electronic chips may be arranged onto the leadframe by surface mounting technology, by a soldering process, may be adhered or may be arranged on the leadframe by any other suitable process. For example, one or more electronic chips may be arranged for each package of the matrix array of packages.

Additional cull and runner can be avoided by the use of the compression molding process. According to this embodiment the test may be performed before packages are singulated and they are still connected to each other after lead isolation. Thus, there may be an increased yield since extra space of the leadframe used for attaching the runners and culls may be saved with this design. Furthermore, the producing of the leadframe may be subjected to less restrictions so that the leadframe may be easily stamped which as well may reduce the costs.

According to an exemplary embodiment of the method the encapsulation material is formed as a continuous strip on the leadframe.

In particular, a unit of packages may be molded in strip form after the assembly process. These units may correspond to rows of the matrix array of packages which rows may be connected to each other by predefined leads, for example. These strips or rows of packages may then be separated by the punching process. In particular, the encapsulation material may form a continuous band or element covering all electronic chips arranged or assembled on a row of the leadframe.

By using a method according to an exemplary embodiment it may be possible to avoid protruding tie bars, in particular in the case that the separating or singularizing of the packages is performed by a sawing process of a strip or row of packages comprising a continuous mold strip. In particular, such a “flushed” encapsulation material edge may be achievable efficiently just by sawing and no dedicated trimming tools may be necessary in order to achieve a “flushed” encapsulation material edge in the area of the tie bars. Thus, no asymmetrical tie bars may be necessary to avoid collisions of tie bars of neighboring packages, which asymmetry may otherwise lead to direct contact to an encapsulation material of the other packages (potential chipping of the mold compound) and an imbalanced tie bar which imbalancing may lead to a risk to the die pad stability.

In the following further exemplary embodiments of the matrix array of packages are described. However, the features and elements of the described embodiments may also be combined with the method of singularizing a matrix array of packages and the method of manufacturing a plurality of packages according to an exemplary embodiment.

According to an exemplary embodiment of the matrix array of packages the leadframe comprises predefined leads on two opposite sides of the chip reception areas, wherein the predefined leads connecting chip reception areas of one column.

In particular, in the case leads are predefined only on two opposite sides of the package, e.g. in the case of dual-flat no-lead packages, the leads are preferably arranged on the sides which connect chip reception areas of one column.

The term “predefined leads” may particularly denote elements or sections of the leadframe which are, after assembling and singularizing the packages, intended to form the leads or connection elements of the singularized package.

According to an exemplary embodiment of the matrix array of packages the predefined leads are separated from each other and tie bars of the leadframe connect chip reception areas of one row.

That is, the matrix array may be separated, e.g. by punching, with respect to the predefined leads (i.e. row wise) but it may not be cut along the predefined cutting areas or cutting lines. Thus, the leadframe or the matrix array of packages may form strips, rows or one dimensional arrays of packages which are electrically separated but still mechanically connected to each other. This strip or row of packages may then be electrically tested. In particular, all packages of the strip may be tested simultaneously, e.g. may be tested with respect to its electrical properties.

According to an exemplary embodiment of the matrix array of packages tie bars of the leadframe are cut along the predefined cutting area.

In particular, several or all tie bars of a row of the matrix array or of the whole matrix array may be cut at the same time or after each other. The cutting of the tie bars may separate or singularize the packages of the matrix array.

According to an exemplary embodiment of the matrix array of packages the encapsulation material and leadframe are cut along same cutting edges.

In particular, the encapsulation material and the leadframe may be cut in a single process step, e.g. along the predefined cutting area formed by predefined cutting lines. Thus, the singularized packages may have a single cutting edge running through the encapsulation material and the leadframe.

According to an exemplary embodiment of the matrix array of packages the predefined cutting area of the encapsulation material is formed by predefined cutting lines and the leadframe comprises predefined cutting lines coinciding with the predefined cutting lines of the encapsulation material.

In particular, the encapsulation material as well as the leadframe may comprise predefined cutting lines forming the predefined cutting area wherein in a top view onto the matrix array the predefined cutting areas may coincide or overlap with each other.

According to an exemplary embodiment of the matrix array of packages the encapsulation material is at least one material out of the group consisting of mold compound laminate; and polymer based material.

The following detailed description refers to the accompanying drawings that show, by way of illustration, specific details and embodiments in which the invention may be practiced.

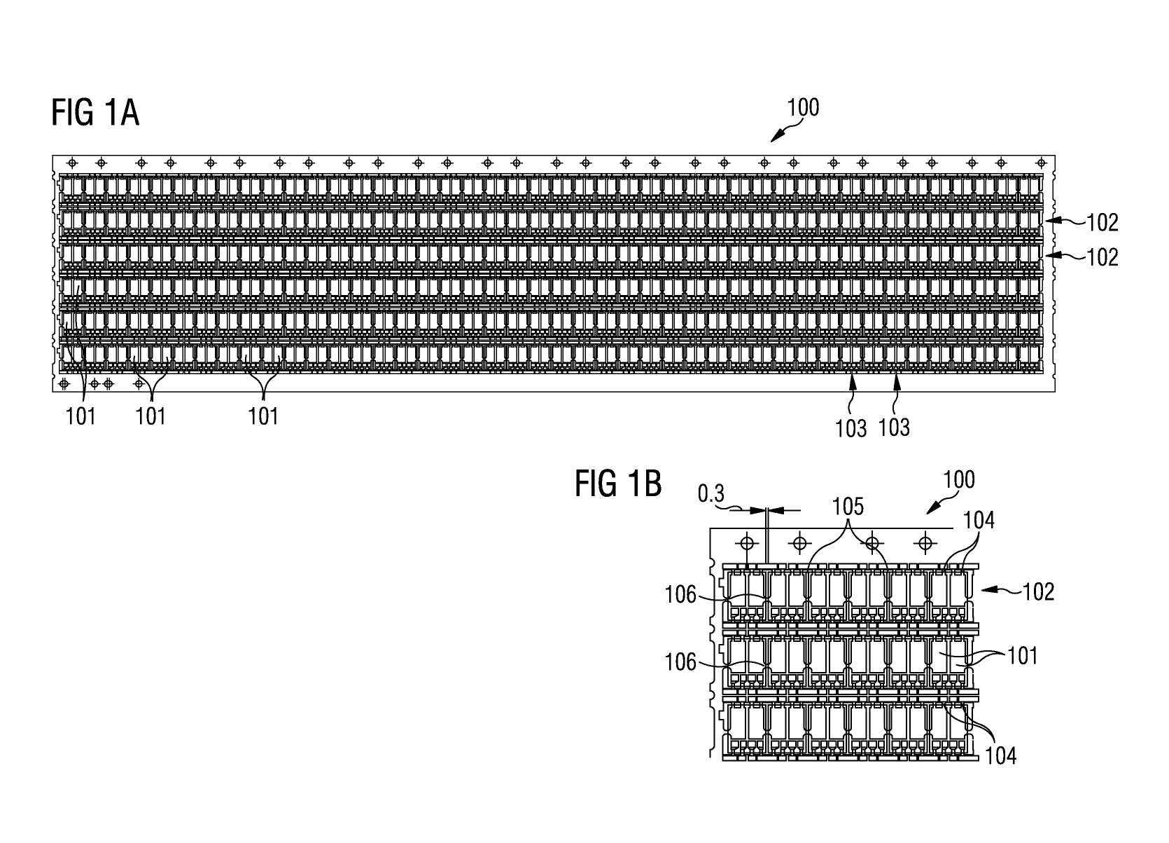

FIGS. 1A and 1B schematically show a leadframe according to an exemplary embodiment. In particular, FIG. 1A shows a leadframe 100 comprising a matrix array of chip reception areas 101 forming rows or strips 102 and columns 103. FIG. 1B depicting a detail of the leadframe 100 showing the chip reception areas 101 having predefined leads 104 at the upper and lower side thereof, i.e. connecting the chip reception areas of a column in the orientation of FIG. 1. Furthermore, predefined cutting areas are schematically indicated by lines 105 separating the chip reception areas 101 of each row 102. The width of this predefined cutting areas may be in the range below 0.75 mm e.g. may be in the range between 0.1 mm and 0.7 mm, preferably in the range between 0.2 mm and 0.5 mm, like 0.3 mm, for example as indicated in FIG. 1B. This range is lower than in common leadframes which are used for matrix arrays of packages which are singulated afterwards by a punching process. The predefined cutting area 105 cross or intersects tie bars 106.

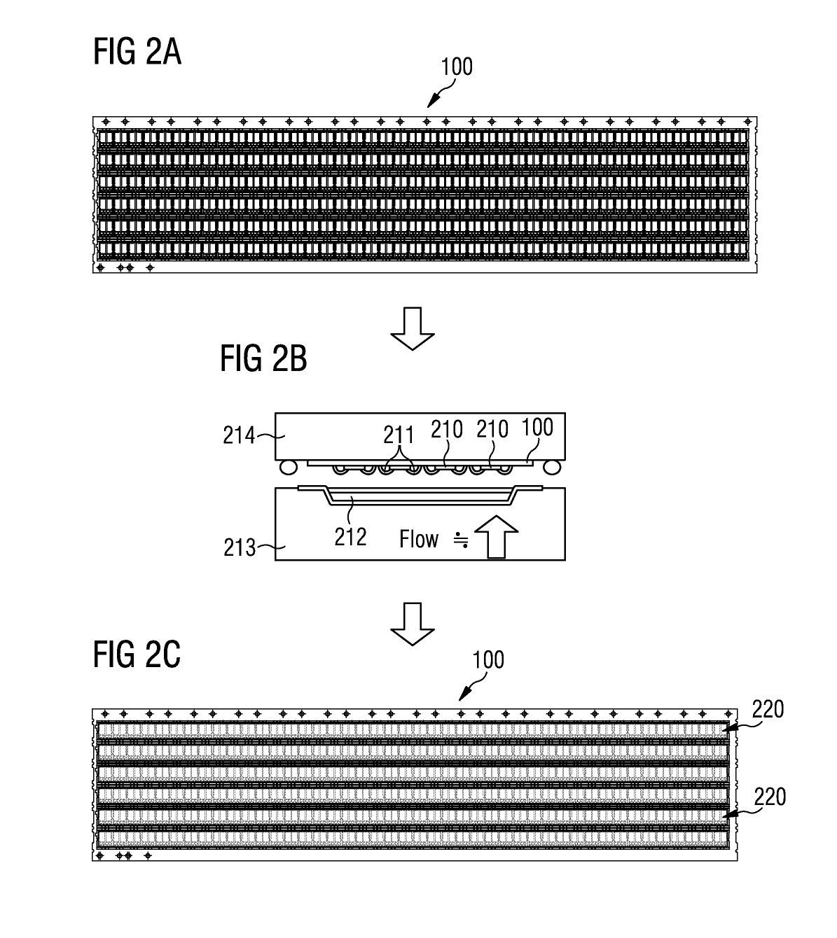

FIGS. 2A to 2C schematically show a compression molding process. In particular, FIG. 2A shows the leadframe 100 of FIG. 1A in a reduced scale, on which the electronic chips are arranged or assembled to. FIG. 2B shows a detailed view of the leadframe 100 having arranged thereon electronic chips 210 which are electrically connected to the leadframe, which is indicated by the wires 211 in FIG. 2B. In the lower portion of FIG. 2B an encapsulation material 212 is schematically depicted arranged in a recess of a stamp or punch 213. The punch 213 is then pressed onto the leadframe 100 arranged on a supporting structure 214 for the compression molding. Additionally some spacer 215 are schematically depicted in FIG. 2B which ensure that the leadframe and/or the assembled electronic chips are not damaged by the punch 213. After the molding molded strips 220 are formed on the leadframe 100 each including a row or strip of packages, which is schematically shown in FIG. 2C.

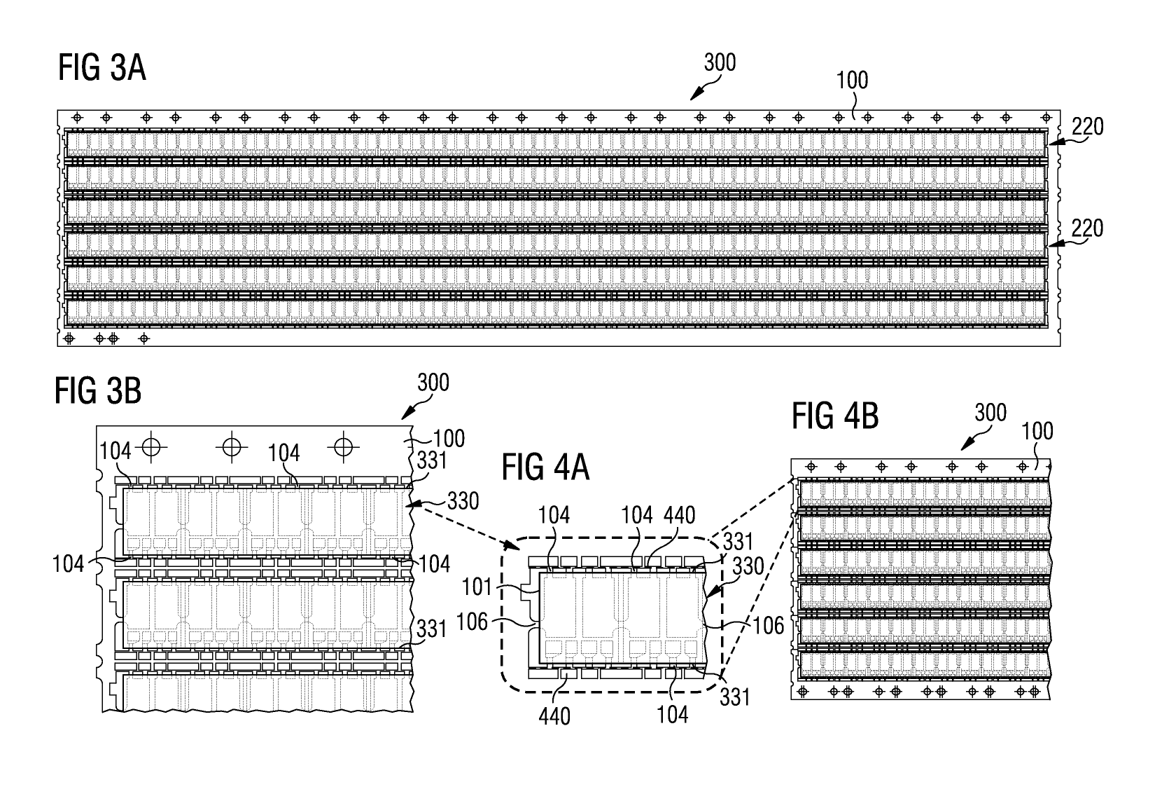

FIGS. 3A and 3B schematically shows a matrix array of packages 300 comprising a leadframe of FIG. 1 after the compression molding process. In particular, FIG. 3A shows the same leadframe 100 of FIG. 2C including the molded strips 220 in a larger view, while FIG. 3B shows a detailed view of the leadframe 100 of FIG. 3A. It should be noted that the predefined leads 104 can be seen in FIG. 3B as well. An encapsulation material 330 is indicated in FIGS. 3A and 3B (as well as in the following FIGS. 4A and 4B) by the horizontal lines 331 forming edges or boundaries of the encapsulation material or mold encapsulation and by dashing the respective lines of the leadframe arranged below the mold compound.

FIGS. 4A and 4B schematically show the matrix array 300 of FIG. 3 and illustrating a punching step. In particular, the predefined leads 104 and the tie bars 106 can be seen in FIG. 4A, connecting the chip reception areas 101 or packages formed therefrom of a respective column and a respective row, respectively. In addition, lines 440 indicate lines along which a punching step is performed in order to separate the predefined leads 104 of a column from each other. It can be seen that by a punching along these lines 440 the leads of a column of the matrix array packages are electrically separated from each other. FIG. 4B shows an overview view of FIG. 4A depicting a larger portion of the matrix array 300 of FIG. 4A.

FIG. 5 schematically shows a cross sectional view of the matrix array 300 of FIG. 4 comprising the encapsulation material 330 arranged on the leadframe 100 and illustrating a sawing process. In particular, a sawing step is schematically indicated by a water jet 551 separating the encapsulation material 330 of a row or strip of packages. However, the sawing step may be performed by mechanical sawing or by laser sawing or cutting. Furthermore, FIG. 5 shows two predefined cutting lines 552 formed or arranged in the encapsulation material 550 and indicating the predefined cutting area. The distance between the two cutting lines is below 0.50 mm, e.g. in the range between 0.02 mm and 0.35 mm, more particularly in the range between 0.05 mm and 0.25 mm, for example, 0.15 mm.

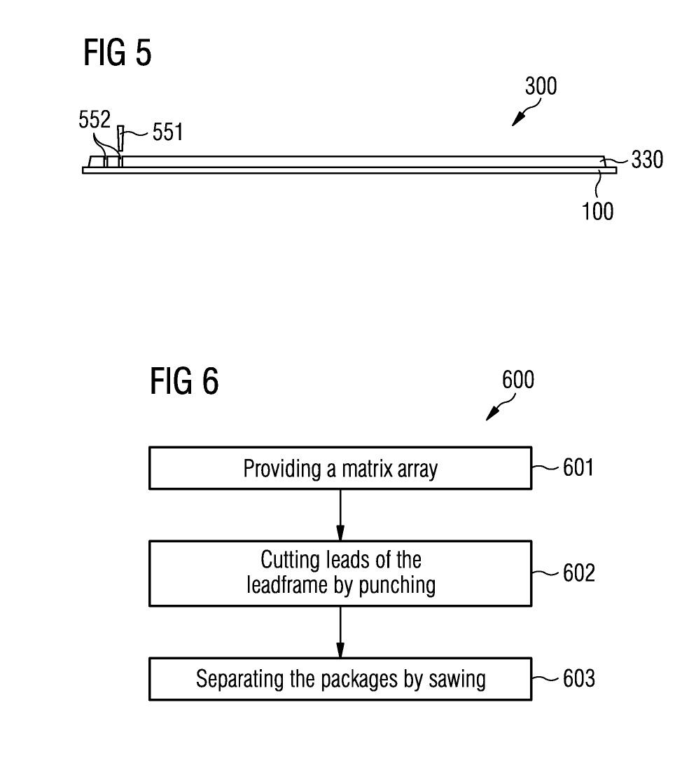

FIG. 6 schematically illustrates a flow chart of a singularizing method 600 according to an exemplary embodiment. In particular the method of singularizing a matrix array of packages 600 comprising providing a matrix array of packages, wherein the matrix array is formed on a leadframe (step 601). In a subsequent step 602 leads of the leadframe are cut by a punching process. In addition, the packages of the matrix array of packages are separated or singularized by a sawing process (step 602). Thus, a hybrid process of singularizing chip packages formed on a leadframe may be provided, wherein the singularizing is performed in two sub-steps, a punching step and a sawing step.

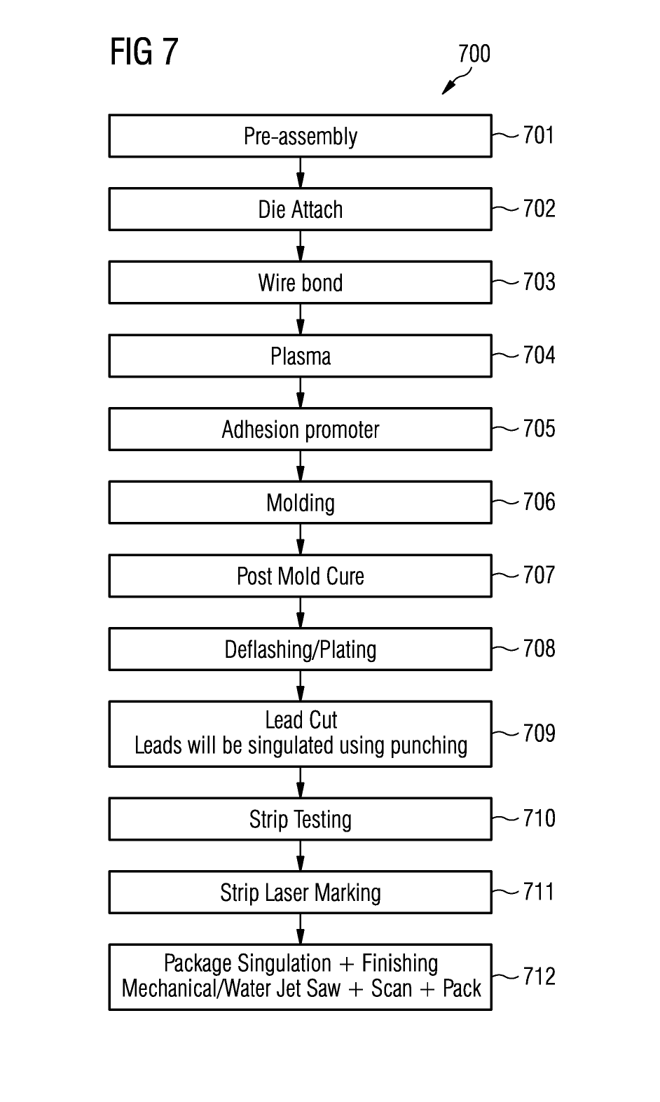

FIG. 7 schematically illustrates a method of manufacturing a plurality of chip packages 700. In a first step (step 701) pre-assembly steps, like providing a leadframe, e.g. a leadframe as shown in FIG. 1, are performed. To this leadframe dices or electronic chips are attached (step 702) and electrically connected, e.g. by bonding, (step 703). Afterwards optional plasma etching may be performed in order to perform patterning process, e.g. to form conduction paths to and from the dies, (step 704). Then in a next optional step an adhesion promoter may be applied in order to improve the adhesion of the mold (step 705). Afterwards a molding process, e.g. a compression molding process, is performed in step 706 forming an encapsulation enclosing the attached or assembled dices. Additionally post mold curing steps may be performed (step 707) which may be followed by deflashing and/or plating processes (step 708).

Subsequently a punching process is performed (step 709) separating predefined leads of the leadframe so that packages which are still connected mechanically in rows or columns to each other are electrically disconnected. Thus, an optional testing may be performed afterwards on a strip level, i.e. on packages which are still mechanically connected and forming strips or rows (step 710). After performing the test the packages of the tested strip and/or the whole strip together may be marked or labelled, e.g. by laser or any other suitable marking method (step 711), for indicating test results, for example. Subsequently, the still mechanically connected packages are singularized by a second singularizing sub-step performed by a sawing step, e.g. by laser, mechanical sawing or water jet sawing (step 712). In the following the singularized packages may be scanned for errors and packed.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of singularizing a matrix array of packages, the method comprising:
providing a matrix array of packages, wherein the matrix array is formed on a leadframe,
cutting predefined leads of the leadframe by a punching process; and
singularizing the packages of the matrix array of packages by a sawing process.

2. The method according to claim 1, wherein the punching process is performed before the sawing process is performed.

3. The method according to claim 1, further comprising:
testing at least one package of the matrix array before the sawing process is performed.

4. The method according to claim 3, wherein the testing is performed for a plurality of packages of a row of the matrix array of packages simultaneously.

5. The method according to claim 3, further comprising:
marking the at least one tested package.

6. The method according to claim 1, further comprising:
forming the matrix array of packages by assembling a plurality of electronic chips onto the leadframe; and
forming an encapsulation material on the leadframe by compression molding.

7. The method according to claim 6, wherein the encapsulation material is formed as a continuous strip on the leadframe.

8. A matrix array of packages, the matrix array of packages comprising:
a leadframe comprising a plurality of chip reception areas arranged in a matrix array comprising rows and columns;
an encapsulation material encapsulating at least a part of the leadframe,
wherein the encapsulation material comprising a predefined cutting area extending perpendicular to rows of the matrix array, wherein the predefined cutting area has a width of less than 0.50 mm.

9. The matrix array of packages according to claim 8, wherein the leadframe comprises predefined leads on two opposite sides of the chip reception areas, wherein the predefined leads connecting chip reception areas of one column.

10. The matrix array of packages according to claim 8, wherein the predefined leads are separated from each other and tie bars of the leadframe connect chip reception areas of one row.

11. The matrix array of packages according to claim 8, wherein tie bars of the leadframe are cut along the predefined cutting area.

12. The matrix array of packages according to claim 8, wherein the encapsulation material and leadframe are cut along same cutting edges.

13. The matrix array of packages according to claim 8, wherein the predefined cutting area of the encapsulation material is formed by predefined cutting lines and the leadframe comprises predefined cutting lines coinciding with the predefined cutting lines of the encapsulation material.

14. The matrix array of packages according to claim 8, wherein the encapsulation material is at least one material out of the group consisting of:
mold compound;
laminate; and
polymer based material.

15. A method for manufacturing a plurality of chip packages, the method comprising:
providing a leadframe comprising a plurality of chip reception areas;
assembling at least one electronic chip onto each of the plurality of chip reception areas;
forming a plurality of packages by molding an encapsulation material onto the assembled electronic chips;
cutting predefined leads of the leadframe by a punching process; and
singularizing the plurality of packages by a sawing process.
